(19) United States
(12) Patent Application Publication
(10) Pub. No.: US 2014/0251539 A1
(43) Pub. Date: Sep. 11, 2014

(54) SUBSTRATE PROCESSING APPARATUS AND SUBSTRATE PROCESSING METHOD

(71) Applicant: Tokyo Electron Limited, Tokyo (JP)

(72) Inventors: Tsuyoshi Mizuno, Kumamoto (JP); Yoichi Tokunaga, Kumamoto (JP); Hiromitsu Namba, Kumamoto (JP); Tatuhiro Ueki, Kumamoto (JP); Jun Nogami, Kumamoto (JP); Jiro Higashijima, Kumamoto (JP); Yoshifumi Amano, Kumamoto (JP); Takatoshi Miyama, Kumamoto (JP)

(73) Assignee: Tokyo Electron Limited, Tokyo (JP)

(21) Appl. No.: 14/198,922

(22) Filed: Mar. 6, 2014

(30) Foreign Application Priority Data
Mar. 11, 2013 (JP) 2013-048123

(51) Int. Cl. H01L 21/67

(52) U.S. Cl. CPC H01L 21/67075; H01L 21/67017; H01L 21/67023
USPC 156/345.23; 134/104.2

(57) ABSTRACT

Disclosed are a substrate processing apparatus and a substrate processing method configured to perform a processing of a substrate by a processing liquid, in which the processing liquid is supplied to a substrate which rotates to process the substrate. The substrate processing apparatus includes a substrate rotating unit that rotates the substrate, a processing liquid supply unit that supplies the processing liquid to the substrate, a collection cup disposed around the substrate to collect the processing liquid supplied to the substrate, and form an air stream that flows downward from an opening formed at a top of the collection cup through a periphery of an outside of the substrate, and a negative pressure generating unit which is provided at an inside of the collection cup and at an outside of the opening and generates a negative pressure which acts toward the outside of the substrate.

### CROSS-REFERENCE TO RELATED APPLICATIONS

This application is based on and claims priority from Japanese Patent Application No. 2013-048123, filed on Mar. 11, 2013, with the Japan Patent Office, the disclosure of which is incorporated herein in its entirety by reference.

### TECHNICAL FIELD

The present disclosure relates to a substrate processing apparatus and a substrate processing method in which a processing liquid is supplied to a rotating substrate to process the substrate.

### BACKGROUND

When, for example, a semiconductor component or a flat panel display is manufactured, liquid processing has conventionally been performed by using various processing liquids such as, for example, a cleaning liquid or an etching liquid on a substrate such as, for example, a semiconductor wafer or a liquid crystal substrate.

In a substrate processing apparatus used in liquid processing on the substrate, the substrate is rotated by a substrate rotating unit while a processing liquid is supplied toward the substrate by a processing liquid supply unit such that liquid processing is performed on the substrate by the processing liquid within a substrate processing container.

In the substrate processing apparatus, a collection cup is disposed around the substrate so that the processing liquid supplied to the substrate is collected by the collection cup.

The collection cup is connected to a conventional exhaust system in a factory provided with the substrate processing apparatus, and air suctioned from an opening formed at the top of the collection cup is discharged to the outside from the bottom of the collection cup by the exhaust system. Accordingly, an air stream flowing from the above position of the substrate to the downward position of the substrate through the periphery of the outside of the substrate is generated, and then by the air stream, for example, a mist type processing liquid is discharged from the substrate processing container to the outside (See. e.g., Japanese Patent Laid-open Publication No. 2008-34490).

### SUMMARY

The present disclosure provides a substrate processing apparatus that supplies a processing liquid to a rotating substrate to process the substrate. The substrate processing apparatus includes: a substrate rotating unit configured to rotate the substrate, a processing liquid supply unit configured to supply the processing liquid to the substrate, a collection cup disposed around the substrate to collect the processing liquid supplied to the substrate, and form an air stream that flows downward from an opening formed at a top of the collection cup through a periphery of an outside of the substrate, and a negative pressure generating unit provided at an outside of the opening and configured to generate a negative pressure which acts toward the outside of the substrate.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a plan view illustrating a substrate processing apparatus.

FIG. 2 is a plan view illustrating a substrate liquid processing apparatus.

FIG. 3 is a side cross-sectional view of FIG. 2.

FIGS. 4A and 4B are side cross-sectional views of FIG. 3 in a large scale.

FIG. 5 is an explanatory view of an operation of the substrate liquid processing apparatus (a substrate receiving process).

FIG. 6 is an explanatory view of an operation of the substrate liquid processing apparatus (a cleaning process).

FIG. 7 is an explanatory view of an operation of the substrate liquid processing apparatus (a rinse process).

FIG. 8 is an explanatory view of an operation of the substrate liquid processing apparatus (a dry process).

FIG. 9 is an explanatory view of an operation of the substrate liquid processing apparatus (a substrate delivery process).

FIG. 10 is an explanatory view illustrating another substrate liquid processing apparatus.

### DETAILED DESCRIPTION

In the following detailed description, reference is made to the accompanying drawing, which form a part hereof. The illustrative embodiments described in the detailed description, drawing, and claims are not meant to be limiting. Other embodiments may be utilized, and other changes may be made without departing from the spirit or scope of the subject matter presented here.

However, in the above described conventional substrate processing apparatus, an exhaust system of a factory provided with the substrate processing apparatus is used, and thus at the time of processing a substrate, the amount or flow velocity of an air stream generated around the substrate depends on performance of an exhaust unit.

Therefore, when a displacement volume required for the substrate processing apparatus is not obtained from the exhaust system, an air stream suitable for processing of the substrate may not be generated around the substrate. Then, a processing liquid scattered from the rotating substrate may bounce off the inner wall of the collection cup and the processing liquid or particles may be adhered on the front surface of the substrate so that liquid processing of the substrate cannot be satisfactorily performed.

An aspect of the present disclosure is to provide a substrate processing apparatus that supplies a processing liquid to a rotating substrate to process the substrate. The substrate processing apparatus includes: a substrate rotating unit configured to rotate the substrate, a processing liquid supply unit configured to supply the processing liquid to the substrate, a collection cup disposed around the substrate to collect the processing liquid supplied to the substrate, and form an air stream that flows downward from an opening formed at a top of the collection cup through a periphery of an outside of the substrate, and a negative pressure generating unit provided at an outside of the opening and configured to generate a negative pressure which acts toward the outside of the substrate.

The substrate processing apparatus further includes a control unit configured to control the substrate rotating unit, the processing liquid supply unit, and the negative pressure generating unit, in which the control unit controls operation and stopping of the negative pressure generating unit

The control unit controls a degree of the negative pressure generated by the negative pressure generating unit.

The negative pressure generating unit includes at least one gas supply hole formed at the outside of the opening of the collection cup, the gas supply hole being configured to supply a compressed gas which flows along an inner wall of the collection cup, in which the compressed gas is supplied to the gas supply hole to generate the negative pressure which induces the air stream toward the outside of the substrate

The gas supply hole is formed in a slit shape along the opening

The inner wall is formed as a continuous surface which extends to the gas supply hole.

Both the air stream which is induced toward the outside of the substrate by the generated negative pressure, and the compressed gas supplied from the gas supply hole flow along the inner wall of the collection cup.

The collection cup has an annular peripheral wall and a protrusion portion which protrudes from an upper end of the peripheral wall toward a radial inside to form the opening having a smaller diameter than the peripheral wall, wherein a gas supply hole is formed to penetrate the protrusion portion, the gas supply hole being configured to supply a compressed gas which flows along an inner wall of the collection cup.

The gas supply hole is formed in plural numbers.

A gas flow path which has a wider width than the gas supply hole within the gas flow path is formed above the gas supply hole and above the protrusion portion.

The gas flow path is formed within an annular cover having a gantry-shaped cross-section.

A connecting tube configured to supply the compressed gas is connected to an outer periphery of the cover.

A supply port of the compressed gas supplied from the connecting tube to the gas flow path is formed in a direction intersecting with an opening direction of the gas supply hole formed in the protrusion portion.

The connecting tube is connected in plural numbers, and the gas supply hole is formed in plural numbers.

The gas supply hole is formed in a slit shape along the opening.

An inner surface of the peripheral wall and an inner surface of the protrusion portion are configured as a concave surface which extends from an upper portion of the peripheral wall to a lower portion of the protrusion portion, the inner surface of the protrusion portion continued to a lower portion of the gas supply hole is configured as a continuous surface including a convex curved surface, and the inner surface of the protrusion portion continued from the lower portion of the gas supply hole to the opening is configured as a continuous surface including a convex curved surface.

The gas flow path is formed within an annular cover, a connecting tube configured to supply the compressed gas is connected to an outer periphery of the cover, and a supply port of the compressed gas supplied from the connecting tube to the gas flow path is formed in a direction intersecting with an opening direction of the gas supply hole formed in the protrusion portion.

The connecting tube is connected in plural numbers, and the gas supply hole is formed in plural numbers.

In the present disclosure, a displacement volume required for processing of a substrate may be obtained without depending on the performance of an exhaust system of a factory.

Hereinafter, a specific configuration of a substrate processing apparatus and a substrate processing method according to the present disclosure will be described with reference to drawings.

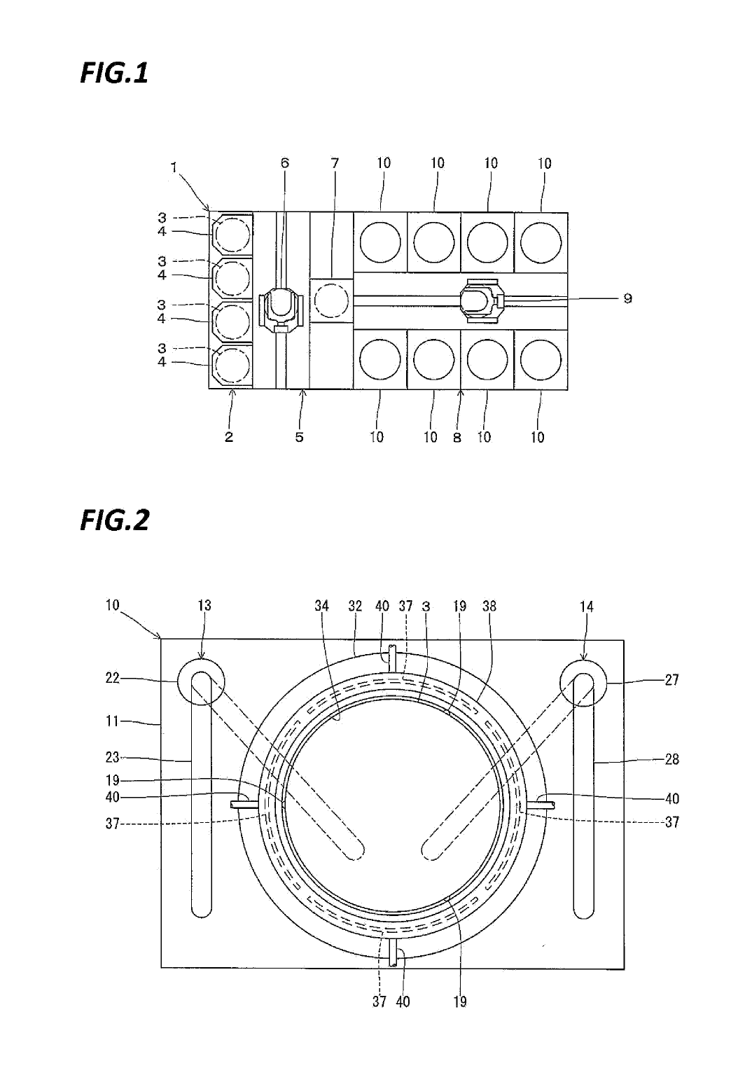

As illustrated in FIG. 1, at the front end of a substrate processing apparatus 1, a carrying-in/out unit 2 is formed. Carriers 4 accommodating a plurality of substrates 3 (for example, 25 substrates) (herein, semiconductor wafers) are carried into or out of the carrying-in/out unit 2, and are placed laterally abreast.

The substrate processing apparatus 1 includes a conveyance unit 5 formed behind the carrying-in/out unit 2. The conveyance unit 5 includes a substrate conveyance device 6 disposed at the front side, and a substrate delivery unit 7 disposed at the rear side. In the conveyance unit 5, the substrates 3 is conveyed by using the substrate conveyance device 6 between any one of the carriers 4 placed in the carrying-in/out unit 2 and the substrate delivery unit 7.

The substrate processing apparatus 1 includes a processing unit 8 formed behind the conveyance unit 5. In the processing unit 8, a substrate conveyance device 9 is disposed at the central portion of the processing unit 8 to extend in a front-rear direction, and substrate liquid processing devices 10 configured to perform liquid processing on substrates 3 are disposed at the left and right sides of the substrate conveyance device 9 to be arranged in a front-rear direction. In the processing unit 8, the substrates 3 are conveyed by using the substrate conveyance device 9 between the substrate delivery unit 7 and the substrate liquid processing devices 10 and are subjected to liquid processing by using the substrate liquid processing devices 10.

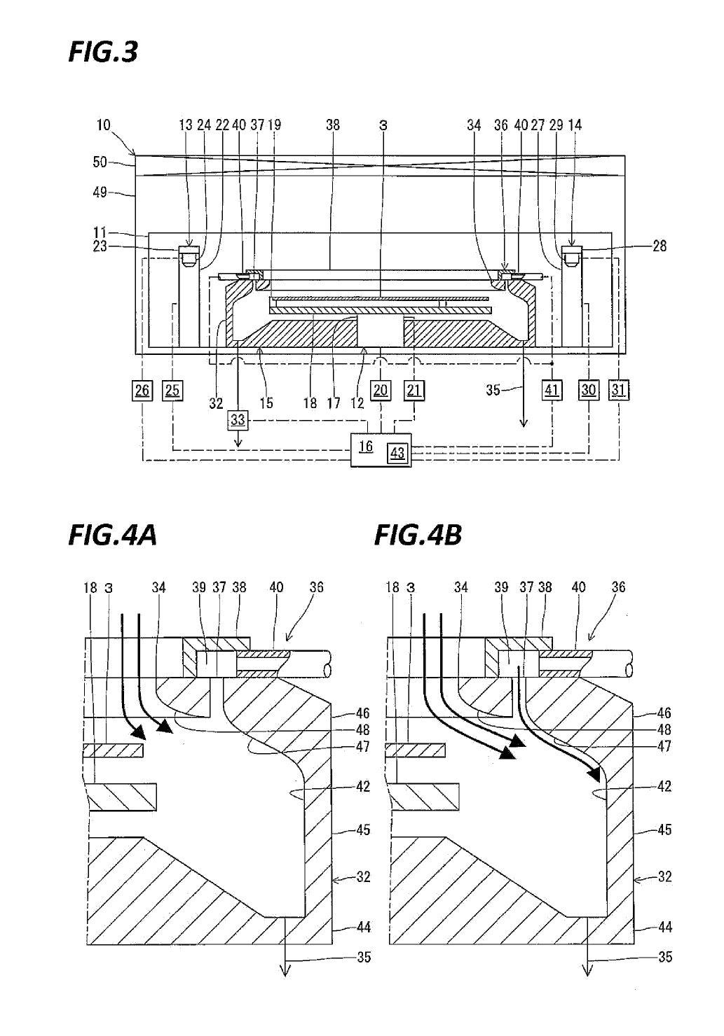

The substrate liquid processing device 10, as illustrated in FIGS. 2 and 3, includes a substrate rotating unit 12, a cleaning liquid supply unit 13 and a rinse liquid supply unit 14 as processing liquid supply units, and a drainage unit 15 which are provided in a substrate processing container 11. The substrate rotating unit 12, the cleaning liquid supply unit 13, the rinse liquid supply unit 14 and the drainage unit 15 are connected to a control unit 16 and their driving is controlled by the control unit 16. The substrate liquid processing device 10 includes a housing 49 which accommodates the substrate processing container 11 therewithin, and a fan filter unit 50 is attached to the top portion of the housing 49 in order to supply clean air to the substrate processing container 11.

The substrate rotating unit 12 includes a rotation shaft 17 which is provided within the substrate processing container 11 to extend vertically, a disk-shaped turn table 18 horizontally attached at the upper end of the rotation shaft 17, and three substrate holders 19 which are attached at the outer periphery of the turn table 18 at equal intervals in the circumferential direction.

In the substrate rotating unit 12, the rotation shaft 17 is connected to a substrate rotation mechanism 20 and a substrate elevating mechanism 21. Rotation or elevation of the substrate rotation mechanism 20 and the substrate elevating mechanism 21 is controlled by the control unit 16.

The substrate rotating unit 12 horizontally holds a substrate 3 by the substrate holders 19 of the turn table 18. The substrate rotating unit 12 rotates the substrate 3 held by the turn table 18 by using the substrate rotation mechanism 20, and moves up and down the turn table 18 and the substrate 3 held by the turn table 18 by using the substrate elevating mechanism 21.

A processing liquid supply unit is constituted by the cleaning liquid supply unit 13 configured to supply a cleaning liquid (a chemical liquid) as a processing liquid, and the rinse liquid supply unit 14 configured to a rinse liquid (pure water) as a processing liquid.

The cleaning liquid supply unit 13 includes a supporting shaft 22 which is provided within the substrate processing container 11 to extend vertically, an arm 23 horizontally attached at the upper end of the supporting shaft 22, and a cleaning liquid ejecting nozzle 24 which is attached at the lower side of the distal end of the arm 23 to be directed downward to the substrate 3. A cleaning liquid ejecting nozzle moving mechanism 25 is connected to the supporting shaft 22. The driving of the cleaning liquid ejecting nozzle moving mechanism 25 is controlled by the control unit 16.

The cleaning liquid supply unit 13 is connected to a cleaning liquid supply mechanism 26 configured to supply a cleaning liquid to the cleaning liquid ejecting nozzle 24. Supply of the cleaning liquid supply mechanism 26 is controlled by the control unit 16.

In the cleaning liquid supply unit 13, the cleaning liquid ejecting nozzle 24 reciprocates between the center above the substrate 3 (start position) and the periphery of the outside of the substrate 3 (retreat position) by the cleaning liquid ejecting nozzle moving mechanism 25, and a cleaning liquid is supplied toward the front surface (top surface) of the substrate 3 from the cleaning liquid ejecting nozzle 24 by the cleaning liquid supply mechanism 26.

The rinse liquid supply unit 14 includes a supporting shaft 27 which is provided within the substrate processing container 11 to extend vertically, an arm 28 horizontally attached at the upper end of the supporting shaft 27, and a rinse liquid ejecting nozzle 29 which is attached at the lower side of the distal end of the arm 28 to be directed downward to the substrate 3. A rinse liquid ejecting nozzle moving mechanism 30 is connected to the supporting shaft 27. The driving of the rinse liquid ejecting nozzle moving mechanism 30 is controlled by the control unit 16.

The rinse liquid supply unit 14 is connected to a rinse liquid supply mechanism 31 configured to supply a rinse liquid to the rinse liquid ejecting nozzle 29. Supply of the rinse liquid supply mechanism 31 is controlled by the control unit 16.

In the rinse liquid supply unit 14, the rinse liquid ejecting nozzle 29 reciprocates between the center above the substrate 3 (start position) and the periphery of the outside of the substrate 3 (retreat position) by the rinse liquid ejecting nozzle moving mechanism 30, and a rinse liquid is supplied toward the front surface (top surface) of the substrate 3 from the rinse liquid ejecting nozzle 29 by the rinse liquid supply mechanism 31.

The drainage unit 15 includes an annular collection cup 32 disposed around the substrate 3, and a drainage mechanism 33 connected to the lower portion (bottom) inside the collection cup 32. The driving of the drainage mechanism 33 is controlled by the control unit 16.

The drainage unit 15 collects the processing liquid supplied to the front surface of the substrate 3 by the collection cup 32, and discharges the collected processing liquid by the drainage mechanism 33 from the collection cup 32 to the outside.

The collection cup 32 has a disk-shaped a bottom portion 44, an annular peripheral wall 45 upwardly erecting from the outer periphery of the bottom portion 44, and a protrusion portion 46 which protrudes from the upper end of the peripheral wall 45 toward the radial inside to form a circular opening 34 having a smaller diameter than the peripheral wall 45. The opening 34 is formed to have a much larger size than the substrate 3 such that the substrate 3 may be moved up and down through the opening 34 during carrying-in/out of the substrate 3.

In the collection cup 32, an exhaust path 35 is connected to the bottom portion 44. Accordingly, the air within the substrate processing container 11, which has been suctioned from the opening 34 at the top of the collection cup 32, is discharged from the bottom portion 44 of the collection cup 32 to the outside. Here, an air stream flowing from the above position of the substrate 3 to the downward position of the substrate 3 through the periphery of the outside of the substrate 3 is generated. By the air stream, for example, a mist type processing liquid is discharged from the substrate processing container 11 to the outside (see FIG. 4A). The exhaust path 35 may be integrally inserted within the substrate processing apparatus 1.

In the collection cup 32, a negative pressure generating unit 36 is formed at the inside of the collection cup 32 and at the outside of the opening 34. The negative pressure generating unit 36 is configured to generate a negative pressure to induce the inside air stream to the outside of the substrate 3. In the present exemplary embodiment, the negative pressure generating unit 36 is formed in the protrusion portion 46 above the substrate 3.

More specifically, the negative pressure generating unit 36 includes four gas supply holes 37 circumferentially formed in a circular arc slit with a predetermined width. The gas supply holes 37 are formed in the protrusion portion 46 at the outside of the opening 34 along the circumference of the opening 34. The gas supply holes 37 are formed to penetrate the protrusion portion 46. The gas supply holes 37 only have to be formed in a shape enough to generate a negative pressure, and the number of the gas supply holes 37 may be one or more and is not limited to four. Preferably, a plurality of gas supply holes 37 may easily generate a negative pressure.

An annular cover 38 having a reversed-U shaped cross-section (a gantry-shaped cross-section) is attached above the four gas supply holes 37 and above the protrusion portion 46. Within the cover 38, a gas flow path 39 having a wider width than the gas supply hole 37 is formed. Four connecting tubes 40 are attached to the outer periphery of the cover 38 in the circumferential direction at equal intervals, and a compressed gas supply mechanism 41 configured to supply a compressed gas is connected to the connecting tubes 40. The control of operation and stopping and the control of flow rate of the compressed gas supply mechanism 41 are performed by the control unit 16. The connecting tubes 40 only have to supply the compressed gas to the gas supply holes 37, and the number of the connecting tubes 40 may be one or more and is not limited to four. Preferably, a plurality of connecting tubes 40 may easily efficiently supply the compressed gas to the gas supply holes 37. It is desirable that the supply direction of the compressed gas supplied from the connecting tubes 40 to the gas flow path 39 intersects the direction of the compressed gas flowing in the gas supply holes 37 formed in the protrusion portion 46. Accordingly, supply ports of the compressed gas supplied from the connecting tubes 40 to the gas flow path 39 are formed in a direction intersecting with the opening direction of the gas supply holes 37 formed in the protrusion portion 46. This may make the compressed gas within the gas flow path 39 more uniform.

An inner wall 42 of the collection cup 32 includes the inner surface of the peripheral wall 45 and the inner surface of the protrusion portion 46, as a concave surface which extends from the upper portion of the peripheral wall 45 to the lower portion of the protrusion portion 46. Also, the inner wall 42 includes the inner surface of the protrusion portion 46 continued from the lower portion of the gas supply hole 37, as a continuous surface constituted by a convex curved portion 47. The inner wall 42 includes the inner surface of the protrusion portion 46 continued from the lower portion of the gas supply hole 37 to the opening 34, as a continuous surface constituted by a convex curved portion 48.

The negative pressure generating unit 36 is placed in a stop state without generation of a negative pressure, as illustrated in FIG. 4A, when a compressed gas is not supplied to the gas supply holes 37 of the collection cup 32 by the compressed gas supply mechanism 41. As illustrated in FIG. 4B, the negative pressure generating unit 36 is placed in an operational state in which a compressed gas is flowed along the inner wall 42 from the gas supply holes 37, and thus a negative pressure is generated by the Coanda effect when the compressed gas is supplied to the gas supply holes 37 of the collection cup 32 by the compressed gas supply mechanism 41. In the operational state, an air stream flowing from the above position of the substrate 3 to the downward position of the substrate 3 through the periphery of the outside of the substrate 3 is induced to the outside of the substrate 3 along the inner wall 42 by a negative pressure due to the Coanda effect, and thus the flow rate or the flow velocity of the air stream passing through the periphery of the outside of the substrate 3 is increased. The flow rate or the flow velocity of the air stream may be controlled through a flow rate or a flow velocity of the compressed gas supplied by the compressed gas supply mechanism 41.

In the negative pressure generating unit 36, the gas flow path 39 having a wider width than the gas supply hole 37 is formed above the gas supply holes 37, and thus serves as a damper so that the compressed gas may be uniformly supplied from the gas supply holes 37 at a predetermined flow rate and a predetermined flow velocity. Since the curved portion 47 including a surface continued from the gas supply holes 37 is formed below the gas supply holes 37, an air stream or a compressed gas becomes a laminar flow to smoothly flow along the curved portion 47. Accordingly, the Coanda effect may easily occur. Since the curved portion 48 including a surface continued from the opening 34 is formed below the opening 34, an air stream suctioned from the opening 34 becomes a laminar flow to smoothly flow along the curved portion 48.

The position where the negative pressure generating unit 36 configured to generate a negative pressure through the Coanda effect is provided is not limited to the inside of the collection cup 32, but the negative pressure generating unit 36 may be provided in the middle of the exhaust path 35. For example, as illustrated in FIG. 10, a negative pressure generating unit 36′ is provided in the middle of the exhaust path 35 of the collection cup 32, and a compressed gas supply unit 41′ is connected to the negative pressure generating unit 36′. Then, a compressed gas is supplied from the compressed gas supply unit 41′ to the negative pressure generating unit 36′ to generate the Coanda effect. Accordingly, an air stream flowing from the collection cup 32 to the exhaust path 35 is induced along the flow of the compressed gas, and thereby the flow rate or the flow velocity of the air stream flowing within the collection cup 32 may be increased.

The substrate processing apparatus 1 is configured as described above, and is controlled by the control unit 16 in accordance with various programs recorded in a recording medium 43 provided in the control unit 16 (a computer) to process a substrate 3. Here, the recording medium 43 stores various setting data or programs therein, and is constituted by a conventionally known thing such as a memory (e.g., a ROM or a RAM), and a disk type recording medium (e.g., a hard disk, a CD-ROM, a DVD-ROM or a flexible disk).

The substrate processing apparatus 1 performs cleaning processing on the substrate 3 as described below in accordance with a substrate processing program recorded in the recording medium 43.

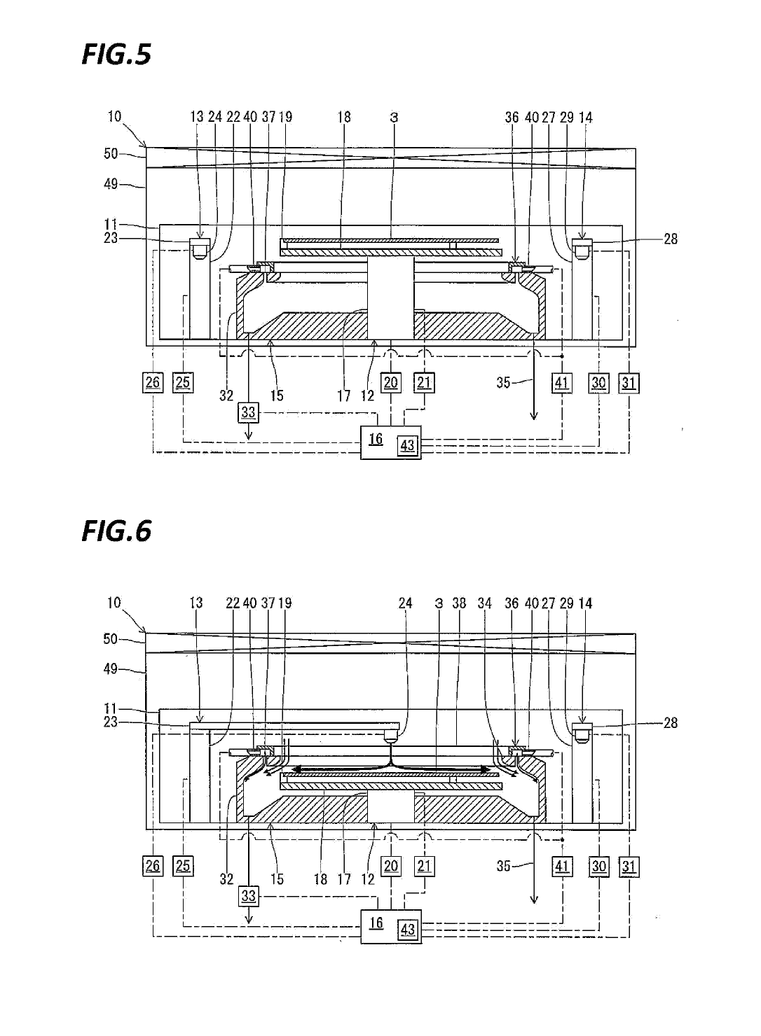

First, in the substrate processing apparatus 1, a substrate 3 conveyed by the substrate conveyance device 9 is received by the substrate liquid processing device 10, as illustrated in FIG. 5 (a substrate receiving process).

In the substrate receiving process, the turn table 18 is moved up to a predetermined position by the substrate elevating mechanism 21 of the substrate rotating unit 12. Then, one substrate 3 conveyed from the substrate conveyance device 9 into the substrate processing container 11 is received while the substrate 3 is horizontally held by the substrate holders 19. Then, the turn table 18 is moved down to a predetermined position by the substrate elevating mechanism 21. The cleaning liquid ejecting nozzle 24 and the rinse liquid ejecting nozzle 29 are retreated to a retreat position at a more outer side than the outer periphery of the turn table 18.

Subsequently, the substrate processing apparatus 1, as illustrated in FIG. 6, processes the front surface of the substrate 3 by a cleaning liquid (a cleaning process).

In the cleaning process, the supporting shaft 22 is rotated by the cleaning liquid ejecting nozzle moving mechanism 25 of the cleaning liquid supply unit 13 to move the cleaning liquid ejecting nozzle 24 to a supply start position above the center of the substrate 3. The turn table 18 is rotated at a predetermined rotation speed by the substrate rotation mechanism 20 of the substrate rotating unit 12 to rotate the substrate 3. Then, the cleaning liquid at a predetermined flow rate is ejected toward the front surface of the substrate 3 from the cleaning liquid ejecting nozzle 24 by the cleaning liquid supply mechanism 26 of the cleaning liquid supply unit 13. The cleaning liquid ejecting nozzle 24 reciprocates horizontally along the substrate 3 by the cleaning liquid ejecting nozzle moving mechanism 25 of the cleaning liquid supply unit 13. The cleaning liquid supplied to the substrate 3 is collected by the collection cup 32 and discharged to the outside by the drainage mechanism 33. At the final stage of the cleaning process, the supporting shaft 22 is rotated by the cleaning liquid ejecting nozzle moving mechanism 25 of the cleaning liquid supply unit 13 to move the cleaning liquid ejecting nozzle 24 to the retreat position at a more outer side than the outer periphery of the substrate 3. The ejection of the cleaning liquid is stopped by the cleaning liquid supply mechanism 26 of the cleaning liquid supply unit 13.

In the cleaning process, the substrate processing apparatus 1 operates the negative pressure generating unit 36. That is, a compressed gas at a predetermined flow rate is supplied to the gas supply holes 37 of the collection cup 32 by the compressed gas supply mechanism 41. The compressed gas flows along the inner wall 42 from the gas supply holes 37. Then, by generation of a negative pressure through the Coanda effect, an air stream which has been flowed into the collection cup 32 from the opening 34 of the collection cup 32 and flows from an above position of the substrate 3 to the downward position of the substrate 3 through the periphery of the outside of the substrate 3 is induced to the outside of the substrate 3 along the inner wall 42 of the collection cup 32, and the flow rate or flow velocity of the air stream is increased.

As described above, the air stream passing through the vicinity of the substrate 3 is induced to the outside of the substrate 3, and the flow rate or flow velocity of the air stream is increased. Therefore, the cleaning liquid or mists of the cleaning liquid which has been supplied to the front surface of the substrate 3 from the cleaning liquid ejecting nozzle 24 is smoothly discharged from the collection cup 32 together with the air stream flowing along the inner wall 42. Accordingly, the mists of the cleaning liquid scattered form the rotating substrate 3 may be suppressed from being bounced off the inner wall of the collection cup 32 and adhered on the front surface of the substrate 3. Since the mists of the cleaning liquid may be efficiently discharged, cleaning processing of the substrate 3 may be satisfactorily performed.

In the cleaning process, the substrate processing apparatus 1 supplies a compressed gas at a predetermined flow rate at a predetermined pressure from the compressed gas supply mechanism 41 such that the degree of the negative pressure generated by the negative pressure generating unit 36 may be constant, but the present disclosure is not limited thereto. A control may be made such that the pressure or flow rate of the compressed gas supplied from the compressed gas supply mechanism 41 may be varied according to, for example, the flow rate of the cleaning liquid or the elapse of time from the cleaning processing start so as to vary the degree of the negative pressure generated by the negative pressure generating unit 36.

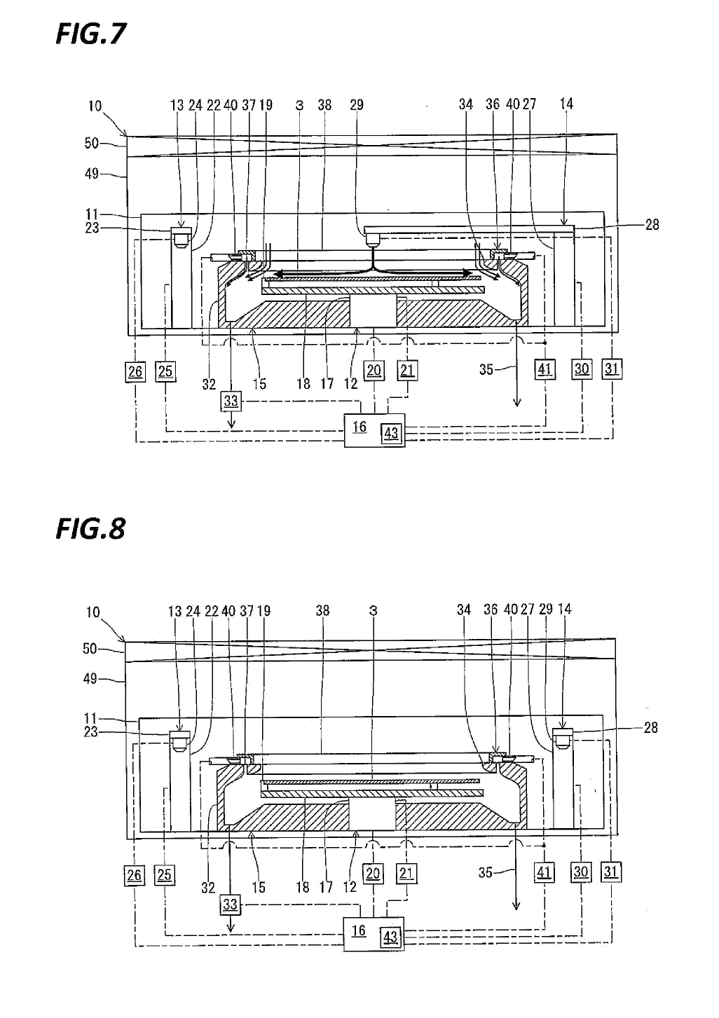

Subsequently, the substrate processing apparatus 1, as illustrated in FIG. 7, processes the front surface of the substrate 3 by a rinse liquid (a rinse process).

In the rinse process, the supporting shaft 27 is rotated by the rinse liquid ejecting nozzle moving mechanism 30 of the rinse liquid supply unit 14 to move the rinse liquid ejecting nozzle 29 to a supply start position above the center of the substrate 3. The turn table 18 is rotated at a predetermined rotation speed by the substrate rotation mechanism 20 of the substrate rotating unit 12 to rotate the substrate 3. Then, the rinse liquid at a predetermined flow rate is ejected toward the front surface of the substrate 3 from the rinse liquid ejecting nozzle 29 by the rinse liquid supply mechanism 31 of the rinse liquid supply unit 14. The rinse liquid ejecting nozzle 29 reciprocates horizontally along the substrate 3 by the rinse liquid ejecting nozzle moving mechanism 30 of the rinse liquid supply unit 14. The rinse liquid supplied to the substrate 3 is collected by the collection cup 32 and discharged to the outside by the drainage mechanism 33. At the final stage of the rinse process, the supporting shaft 27 is rotated by the rinse liquid ejecting nozzle moving mechanism 30 of the rinse liquid supply unit 14 to move the rinse liquid ejecting nozzle 29 to the retreat position at a more outer side than the outer periphery of the substrate 3. The ejection of the rinse liquid is stopped by the rinse liquid supply mechanism 31 of the rinse liquid supply unit 14.

In the rinse process, like in the cleaning process, the substrate processing apparatus 1 operates the negative pressure generating unit 36. Accordingly, the air stream passing through the vicinity of the substrate 3 is induced to the outside of the substrate 3, and the flow rate or flow velocity of the air stream is increased. Therefore, the rinse liquid which has been supplied to the front surface of the substrate 3 from the rinse liquid ejecting nozzle 29 is smoothly discharged from the collection cup 32 together with the air stream. Accordingly, the rinse liquid scattered form the rotating substrate 3 may be suppressed from being bounced off the inner wall of the collection cup 32 and adhered on the front surface of the substrate 3 so that the rinse processing of the substrate 3 may be satisfactorily performed. A control may be made such that the degree of the negative pressure may be varied according to, for example, the flow rate of the rinse liquid or the elapse of time from the rinse processing start. For example, when a predetermined time has elapsed from the start of the rinse process, the negative pressure generated by the negative pressure generating unit 36 may be reduced. At the start of the rinse processing, the mists of the cleaning liquid generated in the cleaning process may remain above the substrate 3. At the initial stage of the rinse process, the mists of the cleaning liquid may be discharged and thus may be suppressed from being adhered on the substrate 3. Thus, the cleaning of the substrate 3 may be satisfactorily performed.

Subsequently, the substrate processing apparatus 1, as illustrated in FIG. 8, performs dry processing of the substrate 3 while rotating the substrate 3 such that the rinse liquid is shaken off and removed from the front surface of the substrate 3 (a dry process).

In the dry process, the turn table 18 is rotated by the substrate rotation mechanism 20 of the substrate rotating unit 12 at a higher rotation speed than that in the cleaning process or the rinse process to rotate the substrate 3. While the substrate 3 is rotated, the rinse liquid remaining on the front surface of the substrate 3 is shaken off by the centrifugal force of the rotating substrate 3, and is removed from the front surface of the substrate 3 so as to dry the substrate 3. The rinse liquid shaken off from the substrate 3 is collected by the collection cup 32 and discharged to the outside by the drainage mechanism 33.

In the dry process, the substrate processing apparatus 1 stops the operation of the negative pressure generating unit 36.

In the dry process, the substrate processing apparatus 1 stops the operation of the negative pressure generating unit 36 from the start to end of the dry processing, but the present disclosure is not limited thereto. At the start of the dry processing, the negative pressure generating unit 36 may be operated to generate a negative pressure, and then the driving of the negative pressure generating unit 36 may be stopped or the degree of the generated negative pressure may be gradually reduced. In this manner, a mist type processing liquid which may be floating around the substrate 3 at the start of the dry processing may be discharged at the initial stage of the dry processing, and thereby suppressed from being adhered on the substrate 3. Therefore, the dry of the substrate 3 may be satisfactorily performed.

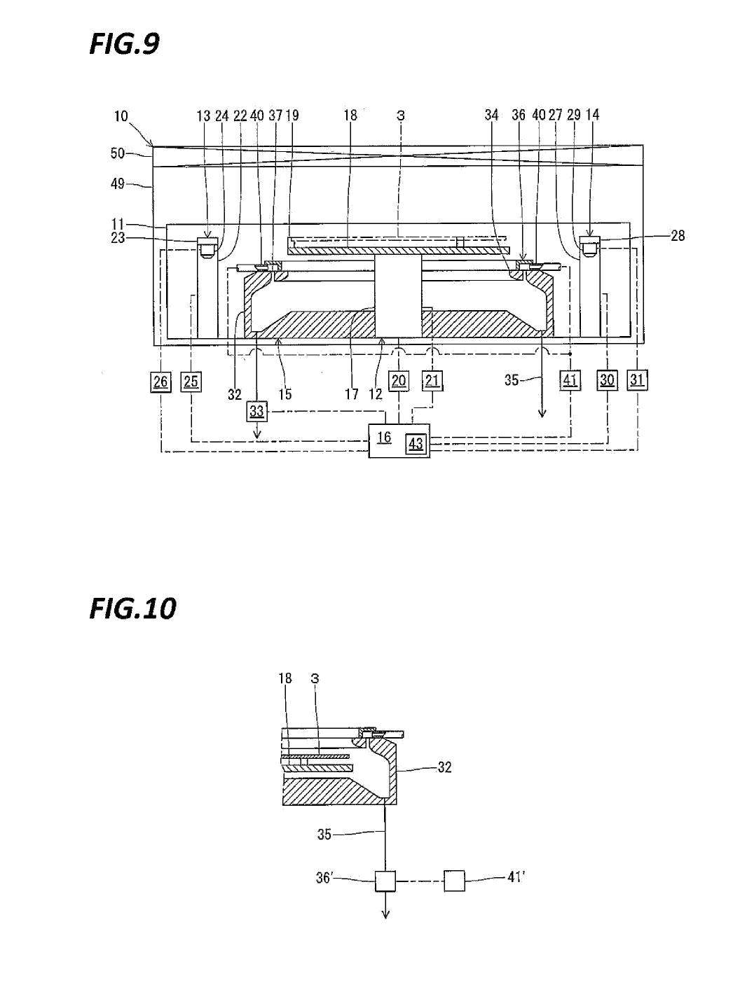

Lastly, the substrate processing apparatus 1, as illustrated in FIG. 9, delivers the substrate 3 from the substrate liquid processing device 10 to the substrate conveyance device 9 (a substrate delivery process).

In the substrate delivery process, the rotation of the turn table 18 by the substrate rotation mechanism 20 of the substrate rotating unit 12 is stopped, and the turn table 18 is moved up to a predetermined position by the substrate elevating mechanism 21. The substrate 3 held by the turn table 18 is delivered to the substrate conveyance device 9. Then, the turn table 18 is moved down to a predetermined position by the substrate elevating mechanism 21. The cleaning liquid ejecting nozzle 24 and the rinse liquid ejecting nozzle 29 are retreated to a retreat position at a more outer side than the outer periphery of the turn table 18.

As described above, in the substrate processing apparatus 1 (the substrate processing method or the substrate processing program performed by the substrate processing apparatus 1), by a collection cup 32 disposed around the substrate 3, a processing liquid (a cleaning liquid or a rinse liquid) supplied to a substrate 3 is collected, and an air stream which is flowing downward from an opening 34 at the top through the periphery of the outside of the substrate 3 is formed. Also, a negative pressure generating unit 36 configured to generate a negative pressure that acts toward the outside of the substrate 3 is formed at the inside of the collection cup 32 and at the outside of the opening 34. Since the negative pressure is generated by the negative pressure generating unit 36, the air stream flowing downward from an above position of the substrate 3 to the downward position of the substrate 3 through the periphery of the outside of the substrate 3 flows along the inner wall 42 of the collection cup 32, that is, toward the outside of the substrate 3. Accordingly, the processing liquid scattered form the rotating substrate 3 may be suppressed from being bounced off the inner wall of the collection cup 32 and adhered on the front surface of the substrate 3. Further, even if a displacement volume required for the substrate processing apparatus 1 cannot be obtained from an exhaust system, processing of the substrate 3 by the processing liquid may be satisfactorily performed. When a negative pressure is generated through the Coanda effect by the negative pressure generating unit 36, the flow rate or flow velocity of the air stream is increased such that the processing of the substrate 3 by the processing liquid may be satisfactorily performed. In the substrate processing apparatus 1, as for the processing liquid, a cleaning liquid or a rinse liquid is used, but the present disclosure is not limited thereto. The same effect may be achieved even in a case where various liquids such as, for example, an etching liquid, a developer, a hydrophobizing liquid are used.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A substrate processing apparatus that supplies a processing liquid to a rotating substrate to process the substrate, comprising:
a substrate rotating unit configured to rotate the substrate,
a processing liquid supply unit configured to supply the processing liquid to the substrate,
a collection cup disposed around the substrate to collect the processing liquid supplied to the substrate, and form an air stream that flows downward from an opening formed at a top of the collection cup through a periphery of an outside of the substrate, and
a negative pressure generating unit provided at an outside of the opening, and configured to generate a negative pressure which acts toward the outside of the substrate.

2. The substrate processing apparatus of claim 1, further comprising a control unit configured to control the substrate rotating unit, the processing liquid supply unit, and the negative pressure generating unit,
wherein the control unit controls operation and stopping of the negative pressure generating unit.

3. The substrate processing apparatus of claim 2, wherein the control unit controls a degree of the negative pressure generated by the negative pressure generating unit.

4. The substrate processing apparatus of claim 1, wherein the negative pressure generating unit includes at least one gas supply hole formed at the outside of the opening of the collection cup, the gas supply hole being configured to supply a compressed gas which flows along an inner wall of the collection cup,
wherein the compressed gas is supplied to the gas supply hole to generate the negative pressure which induces the air stream toward the outside of the substrate.

5. The substrate processing apparatus of claim 4, wherein the gas supply hole is formed in a slit shape along the opening.

6. The substrate processing apparatus of claim 4, wherein the inner wall is formed as a continuous surface which extends to the gas supply hole.

7. The substrate processing apparatus of claim 4, wherein both the air stream which is induced toward the outside of the substrate by the generated negative pressure, and the compressed gas supplied from the gas supply hole flow along the inner wall of the collection cup.

8. The substrate processing apparatus of claim 1, wherein the collection cup has an annular peripheral wall and a protrusion portion which protrudes from an upper end of the peripheral wall toward a radial inside to form the opening having a smaller diameter than the peripheral wall,
wherein a gas supply hole is formed to penetrate the protrusion portion, the gas supply hole being configured to supply a compressed gas which flows along an inner wall of the collection cup.

9. The substrate processing apparatus of claim 8, wherein the gas supply hole is formed in plural numbers.

10. The substrate processing apparatus of claim 8, wherein a gas flow path which has a wider width than the gas supply hole within the gas flow path is formed above the gas supply hole and above the protrusion portion.

11. The substrate processing apparatus of claim 10, wherein the gas flow path is formed within an annular cover having a gantry-shaped cross-section.

12. The substrate processing apparatus of claim 11, wherein a connecting tube configured to supply the compressed gas is connected to an outer periphery of the cover.

13. The substrate processing apparatus of claim 12, wherein a supply port of the compressed gas supplied from the connecting tube to the gas flow path is formed in a direction intersecting with an opening direction of the gas supply hole formed in the protrusion portion.

14. The substrate processing apparatus of claim 13, wherein the connecting tube is connected in plural numbers, and
the gas supply hole is formed in plural numbers.

15. The substrate processing apparatus of claim 13, wherein the gas supply hole is formed in a slit shape along the opening.

16. The substrate processing apparatus of claim 10, wherein an inner surface of the peripheral wall and an inner surface of the protrusion portion are configured as a concave surface which extends from an upper portion of the peripheral wall to a lower portion of the protrusion portion, the inner surface of the protrusion portion continued to a lower portion of the gas supply hole is configured as a continuous surface including a convex curved surface, and the inner surface of the protrusion portion continued from the lower portion of the gas supply hole to the opening is configured as a continuous surface including a convex curved surface.

17. The substrate processing apparatus of claim 16, wherein the gas flow path is formed within an annular cover,
a connecting tube configured to supply the compressed gas is connected to an outer periphery of the cover, and
a supply port of the compressed gas supplied from the connecting tube to the gas flow path is formed in a direction intersecting with an opening direction of the gas supply hole formed in the protrusion portion.

18. The substrate processing apparatus of claim 17, wherein the connecting tube is connected in plural numbers, and
the gas supply hole is formed in plural numbers.
